(19) United States
(12) Patent Application Publication
(10) Pub. No.: US 2025/0294786 A1
(43) Pub. Date: Sep. 18, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yusuke KOBAYASHI, Yokohama Kanagawa (JP); Takato Yamamoto, Kawasaki Kanagawa (JP); Tatsunori Sakano, Shinagawa Tokyo (JP); Ryohei Gejo, Kawasaki Kanagawa (JP); Tomoko Matsudai, Shibuya Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/019,650

(22) Filed: Jan. 14, 2025

(30) Foreign Application Priority Data
Mar. 13, 2024 (JP) 2024-039372

(51) Int. Cl. H10D 12/00

(52) U.S. Cl. CPC H10D 12/481

(57) ABSTRACT

A second surface-side region includes a fourth semiconductor layer facing at least one of a plurality of second gate electrodes via a second insulating film, a fifth semiconductor layer contacting a second electrode, a sixth semiconductor layer contacting the second electrode, the sixth semiconductor layer being of a first conductivity type and having a higher first-conductivity-type impurity concentration than a first semiconductor layer, and a seventh semiconductor layer contacting the second electrode, the seventh semiconductor layer being of the second conductivity type and having a lower second-conductivity-type impurity concentration than the fourth and fifth semiconductor layers. The seventh semiconductor layer is positioned between the plurality of second gate electrodes in a second direction orthogonal to the first direction.

### CROSS-REFERENCE TO RELATED APPLICATION

This application is based upon and claims the benefit of priority from Japanese Patent Application No. 2024-039372, filed on Mar. 13, 2024; the entire contents of which are incorporated herein by reference.

### FIELD

Embodiments described herein relate generally to a semiconductor device.

### BACKGROUND

An IGBT (Insulated Gate Bipolar Transistor) that has a double-sided gate structure has been proposed in which gate electrodes are located at the front and back sides of a semiconductor layer.

### BRIEF DESCRIPTION OF THE DRAWINGS

FIG. 1 is a schematic cross-sectional view of a semiconductor device of a first embodiment;

FIGS. 2 to 5 are schematic plan views of second surface sides of semiconductor devices of the first embodiment;

FIG. 6 is a schematic cross-sectional view of a semiconductor device according to a modification of the first embodiment;

FIG. 7 is a schematic cross-sectional view of a semiconductor device of a second embodiment;

FIG. 8 is a schematic cross-sectional view of a semiconductor device according to a modification of the second embodiment; and

FIG. 9 is a graph showing simulation results.

### DETAILED DESCRIPTION

According to one embodiment, a semiconductor device includes a first electrode; a second electrode; a semiconductor part positioned between the first electrode and the second electrode in a first direction, the semiconductor part including a first semiconductor layer of a first conductivity type, a first surface-side region positioned between the first electrode and the first semiconductor layer in the first direction, and a second surface-side region positioned between the second electrode and the first semiconductor layer in the first direction; a plurality of first gate electrodes facing the first surface-side region; a plurality of first insulating films located between the first surface-side region and the plurality of first gate electrodes; a plurality of second gate electrodes facing the second surface-side region in the first direction; and a plurality of second insulating films located between the second surface-side region and the plurality of second gate electrodes, the first surface-side region including a second semiconductor layer facing at least one of the plurality of first gate electrodes via the first insulating film, the second semiconductor layer being of a second conductivity type, and a third semiconductor layer contacting the first electrode, the third semiconductor layer being of the first conductivity type and having a higher first-conductivity-type impurity concentration than the first semiconductor layer, the second surface-side region including a fourth semiconductor layer facing at least one of the plurality of second gate electrodes via the second insulating film, the fourth semiconductor layer being of the second conductivity type, a fifth semiconductor layer contacting the second electrode, the fifth semiconductor layer being of the second conductivity type and having a higher second-conductivity-type impurity concentration than the second and fourth semiconductor layers, a sixth semiconductor layer contacting the second electrode, the sixth semiconductor layer being of the first conductivity type and having a higher first-conductivity-type impurity concentration than the first semiconductor layer, and a seventh semiconductor layer contacting the second electrode, the seventh semiconductor layer being of the second conductivity type and having a lower second-conductivity-type impurity concentration than the fourth and fifth semiconductor layers, the seventh semiconductor layer being positioned between the plurality of second gate electrodes in a second direction orthogonal to the first direction.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

### First Embodiment

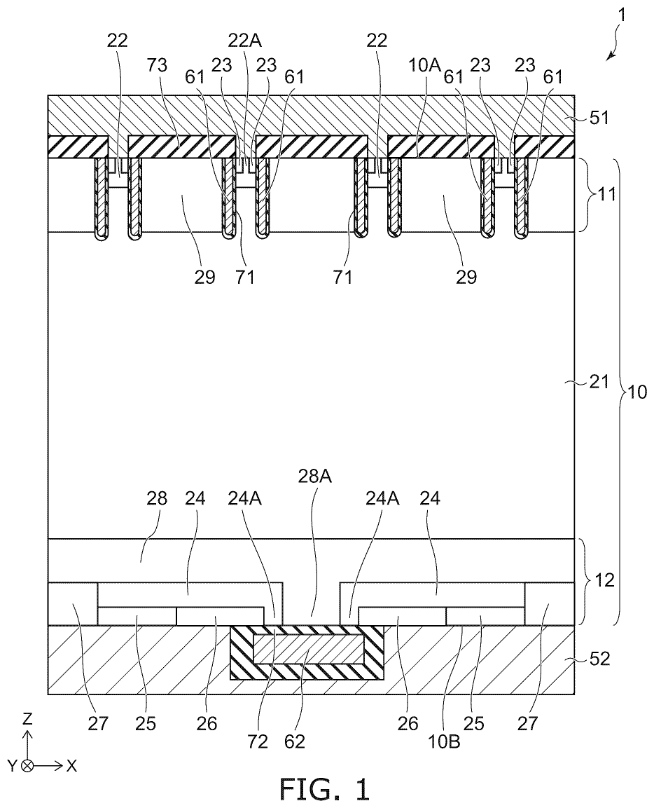

FIG. 1 is a schematic cross-sectional view of a semiconductor device 1 of a first embodiment. The semiconductor device 1 includes a first electrode 51, a second electrode 52, a semiconductor part 10, multiple first gate electrodes 61, multiple first insulating films 71, multiple second gate electrodes 62, and multiple second insulating films 72. The semiconductor device 1 is an IGBT; the first electrode 51 is an emitter electrode; and the second electrode 52 is a collector electrode.

The semiconductor part 10 is positioned between the first electrode 51 and the second electrode 52 in a first direction Z. Two directions orthogonal to the first direction Z are taken as a second direction X and a third direction Y. The second direction X and the third direction Y are orthogonal to each other.

The material of the semiconductor part 10 is, for example, silicon. Or, silicon carbide, gallium nitride, etc., may be used as the material of the semiconductor part 10. In the description of the specification, a first conductivity type of the semiconductor part 10 is taken to be an n-type; and a second conductivity type of the semiconductor part 10 is taken to be a p-type. The first conductivity type may be the p-type; and the second conductivity type may be the n-type.

The semiconductor part 10 includes a first surface 10A, and a second surface 10B positioned at the side opposite to the first surface 10A in the first direction Z. The first electrode 51 faces the first surface 10A in the first direction Z; and the second electrode 52 faces the second surface 10B in the first direction Z.

The semiconductor part 10 includes an n-type first semiconductor layer 21, a first surface-side region 11 positioned between the first electrode 51 and the first semiconductor layer 21 in the first direction Z, and a second surface-side region 12 positioned between the second electrode 52 and the first semiconductor layer 21 in the first direction Z. The first semiconductor layer 21 is a drift layer of an IGBT. The first surface-side region 11 includes the first surface 10A of the semiconductor part 10 and a part of the semiconductor part 10 between the first surface 10A and the first semiconductor layer 21. The second surface-side region 12 includes the second surface 10B of the semiconductor part 10 and a part of the semiconductor part 10 between the second surface 10B and the first semiconductor layer 21.

The first gate electrode 61 faces the first surface-side region 11 of the semiconductor part 10 via the first insulating film 71. The first insulating film 71 is located between the first surface-side region 11 and the first gate electrode 61 and between the first semiconductor layer 21 and the first gate electrode 61. The first gate electrode 61 is located, with the first insulating film 71 interposed, inside a trench that extends in the first direction Z from the first surface 10A and extends through the first surface-side region 11. The multiple first gate electrodes 61 that extend in the third direction Y are arranged in the second direction X. An insulating layer 73 is located between the first gate electrode 61 and the first electrode 51 in the first direction Z; and the first gate electrode 61 does not contact the first electrode 51.

The first surface-side region 11 includes a p-type second semiconductor layer 22 and an n-type third semiconductor layer 23. The second semiconductor layer 22 is a base layer of the IGBT. The third semiconductor layer 23 is an emitter layer of the IGBT.

The second semiconductor layer 22 is positioned on the first semiconductor layer 21 in the first direction Z and contacts the first semiconductor layer 21. The second semiconductor layer 22 is positioned between the first gate electrodes 61 that are adjacent to each other in the second direction X. The side surface of the second semiconductor layer 22 faces the first gate electrode 61 via the first insulating film 71. In other words, the first gate electrode 61 faces the second semiconductor layer 22 via the first insulating film 71 in the second direction X. The second semiconductor layer 22 contacts the first insulating film 71.

The n-type impurity concentration of the third semiconductor layer 23 is greater than the n-type impurity concentration of the first semiconductor layer 21. The third semiconductor layer 23 is positioned on the second semiconductor layer 22 in the first direction Z and contacts the second semiconductor layer 22. The third semiconductor layer 23 contacts the first electrode 51 and is electrically connected with the first electrode 51. Two third semiconductor layers 23 are located between the first gate electrodes 61 that are adjacent to each other in the second direction X; and the two third semiconductor layers 23 are separated from each other in the second direction X. A part 22A of the second semiconductor layer 22 is positioned between the two third semiconductor layers 23; and the part 22A of the second semiconductor layer 22 contacts the first electrode 51. The p-type impurity concentration of the part 22A of the second semiconductor layer 22 is greater than the p-type impurity concentration of the part of the second semiconductor layer 22 other than the part 22A. The third semiconductor layer 23 contacts the first insulating film 71.

The first surface-side region 11 may further include a p-type ninth semiconductor layer 29. The ninth semiconductor layer 29 is positioned between the first gate electrodes 61 that are adjacent to each other in the second direction X. The depth from the first surface 10A of the ninth semiconductor layer 29 is greater than the depth from the first surface 10A of the second semiconductor layer 22. The insulating layer 73 is located between the ninth semiconductor layer 29 and the first electrode 51 in the first direction Z; and the ninth semiconductor layer 29 does not contact the first electrode 51. The third semiconductor layer 23 is not located in the ninth semiconductor layer 29. One side surface of the first gate electrode 61 among the two side surfaces of the first gate electrode 61 in the second direction X is adjacent to the third and second semiconductor layers 23 and 22 with the first insulating film 71 interposed; and the other side surface is adjacent to the ninth semiconductor layer 29 with the first insulating film 71 interposed.

The second gate electrode 62 has a planar-gate structure and faces the second surface-side region 12 in the first direction Z. The second insulating film 72 is located between the second surface-side region 12 and the second gate electrode 62. The second gate electrode 62 is positioned inside the second electrode 52; and the second insulating film 72 is located between the second gate electrode 62 and the second electrode 52. The second insulating film 72 surrounds the upper surface, lower surface, and side surface of the second gate electrode 62. The second gate electrode 62 does not contact the second electrode 52.

The second surface-side region 12 includes a p-type fourth semiconductor layer 24, a p-type fifth semiconductor layer 25, an n-type sixth semiconductor layer 26, and a p-type seventh semiconductor layer 27.

The fourth semiconductor layer 24 includes a first part 24A that faces the second gate electrode 62 in the first direction Z via the second insulating film 72. The first part 24A functions as a channel part as described below. The fourth semiconductor layer 24 contacts the second insulating film 72, the fifth semiconductor layer 25, the sixth semiconductor layer 26, the seventh semiconductor layer 27, and an eighth semiconductor layer 28.

The p-type impurity concentration of the fifth semiconductor layer 25 is greater than the p-type impurity concentration of the second semiconductor layer 22 and the p-type impurity concentration of the fourth semiconductor layer 24. The fifth semiconductor layer 25 contacts the second electrode 52 and is electrically connected with the second electrode 52. The fifth semiconductor layer 25 is a collector layer of the IGBT. The fifth semiconductor layer 25 is positioned between the second electrode 52 and the fourth semiconductor layer 24 in the first direction Z. The fifth semiconductor layer 25 contacts the fourth semiconductor layer 24, the sixth semiconductor layer 26, and the seventh semiconductor layer 27.

The n-type impurity concentration of the sixth semiconductor layer 26 is greater than the n-type impurity concentration of the first semiconductor layer 21. The sixth semiconductor layer 26 contacts the second electrode 52 and is electrically connected with the second electrode 52. The sixth semiconductor layer 26 is positioned between the second electrode 52 and the fourth semiconductor layer 24 in the first direction Z. The sixth semiconductor layer 26 contacts the second insulating film 72, the fourth semiconductor layer 24, and the fifth semiconductor layer 25.

The p-type impurity concentration of the seventh semiconductor layer 27 is less than the p-type impurity concentration of the fourth semiconductor layer 24 and the p-type impurity concentration of the fifth semiconductor layer 25. The seventh semiconductor layer 27 contacts the second electrode 52 and is electrically connected with the second electrode 52. The seventh semiconductor layer 27 is positioned between the second electrode 52 and the eighth semiconductor layer 28 (described below) in the first direction Z. The seventh semiconductor layer 27 contacts the fourth semiconductor layer 24, the fifth semiconductor layer 25, and the eighth semiconductor layer 28. In a plane including the second and third directions X and Y, the fifth semiconductor layer 25 is positioned between the adjacent seventh semiconductor layer 27 and the first part 24A of the adjacent fourth semiconductor layer 24. When comparing the fifth semiconductor layer 25 and the seventh semiconductor layer 27 that contact the same fourth semiconductor layer 24, the distance between the fifth semiconductor layer 25 and the second gate electrode 62 is less than the distance between the seventh semiconductor layer 27 and the second gate electrode 62 in the plane including the second and third directions X and Y. The seventh semiconductor layer 27 is positioned between two second gate electrodes 62 that are adjacent to each other in the plane including the second and third directions X and Y. The seventh semiconductor layer 27 does not overlap the second gate electrode 62 in the first direction Z.

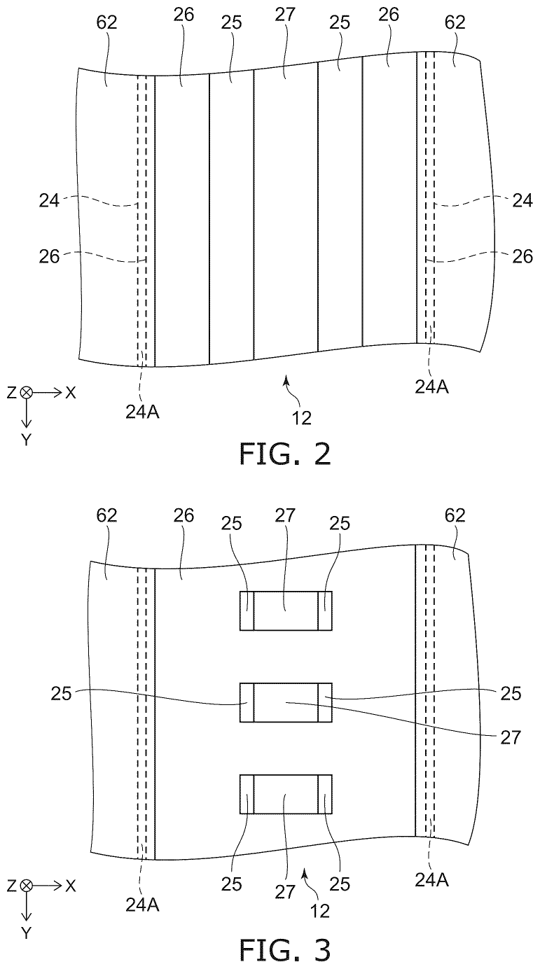

For example, the configuration that is shown in the cross section of FIG. 1 is repeated in the second direction X. The first surface-side region 11 and the second surface-side region 12 are arranged independently of each other. For example, the shape and arrangement spacing of the first gate electrode 61 and the shape and arrangement spacing of the second gate electrode 62 are configured independently of each other. FIGS. 2 to 5 below may be rotated to any angle in the plane including the second and third directions X and Y. The expressions related to the second and third directions X and Y for the second surface-side region 12 and the second gate electrode 62 can be replaced respectively with any mutually-orthogonal fourth and fifth directions in the plane including the second and third directions X and Y. The fourth direction and the fifth direction are not illustrated.

FIG. 2 is a schematic plan view showing an example of an arrangement of the second gate electrodes 62 and the layers of the second surface-side region 12 of the semiconductor device 1. The multiple second gate electrodes 62 are arranged in the second direction X. FIG. 2 shows the layers of the second surface-side region 12 between two second gate electrodes 62 adjacent to each other in the second direction X.

For example, the first part 24A (the channel part) of the fourth to seventh semiconductor layers 24 to 27 extend in the third direction Y.

The first part 24A (the channel part) is adjacent to the sixth semiconductor layer 26 in the second direction X. The seventh semiconductor layer 27 is positioned between the multiple second gate electrodes 62 in the second direction X. In the second direction X, the seventh semiconductor layer 27 is more distant to the second gate electrode 62 than the first part 24A (the channel part). The sixth semiconductor layer 26 is positioned between the first part 24A (the channel part) and the fifth semiconductor layer 25 in the second direction X. The fifth semiconductor layer 25 is positioned between the sixth semiconductor layer 26 and the seventh semiconductor layer 27 in the second direction X.

As shown in FIG. 1, the second surface-side region 12 may further include the eighth semiconductor layer 28. The eighth semiconductor layer 28 is positioned between the first semiconductor layer 21 and the fourth semiconductor layer 24 and between the first semiconductor layer 21 and the seventh semiconductor layer 27 in the first direction Z. The eighth semiconductor layer 28 contacts the fourth and seventh semiconductor layers 24 and 27. The n-type impurity concentration of the eighth semiconductor layer 28 is greater than the n-type impurity concentration of the first semiconductor layer 21. The eighth semiconductor layer 28 is a buffer layer of the IGBT. By including the eighth semiconductor layer 28, the extension of the depletion layer in the off-state of the semiconductor device 1 can be stopped by the eighth semiconductor layer 28; and the thickness (the thickness in the first direction Z) of the first semiconductor layer 21 can be thinner than when the eighth semiconductor layer 28 is not included.

A part 28A of the eighth semiconductor layer 28 extends through the fourth semiconductor layer 24 in the first direction Z and is adjacent to the first part 24A (the channel part) of the fourth semiconductor layer 24 in the first direction X.

By applying a gate voltage that is greater than a first threshold voltage to the first gate electrode 61 in a state in which a positive voltage is applied to the second electrode 52 and the first electrode 51 is set to a ground potential, a first channel (an inversion layer) is formed in the part of the second semiconductor layer 22 facing the first gate electrode 61; and the semiconductor device 1 is set to the on-state. In the on-state, an electron current flows between the first electrode 51 and the second electrode 52 via the third semiconductor layer 23 (the emitter layer), the first channel, the first semiconductor layer 21 (the drift layer), and the fifth semiconductor layer 25 (the collector layer). In the on-state, holes are supplied from the fifth and seventh semiconductor layers 25 and 27 to the first semiconductor layer 21; a high-density state of electrons and holes is formed in the first semiconductor layer 21; and a low on-resistance is obtained. The seventh semiconductor layer 27 also functions as a collector layer, but the p-type impurity concentration of the seventh semiconductor layer 27 is less than the p-type impurity concentration of the fifth semiconductor layer 25, and so the seventh semiconductor layer 27 functions as a low injection region that injects fewer holes than the fifth semiconductor layer 25.

The semiconductor device 1 is switched to the off-state by applying, to the first gate electrode 61, a gate voltage that is less than the threshold voltage. The gate voltage of the second gate electrode 62 is turned on by switching to a voltage that is greater than a second threshold voltage at the turn-off timing at which the gate voltage of the first gate electrode 61 is set to be less than the first threshold voltage. The gate voltage of the second gate electrode 62 is turned on directly before, directly after, or simultaneously with the turn-off of the gate voltage of the first gate electrode 61.

When the gate voltage of the second gate electrode 62 is turned on, a second channel (an inversion layer) is formed in the first part 24A of the fourth semiconductor layer 24; and electrons inside the first semiconductor layer 21 are discharged into the second electrode 52 via the part 28A of the eighth semiconductor layer 28, the second channel, and the sixth semiconductor layer 26. The electrons inside the first semiconductor layer 21 are discharged to the second electrode 52 via a path that does not go through a p-type semiconductor layer. As a result, the injection of holes into the first semiconductor layer 21 can be suppressed, and the turn-off switching loss of the semiconductor device 1 can be reduced. The gate voltage of the second gate electrode 62 is turned off before the gate voltage of the first gate electrode 61 is turned on.

Electrons inside regions of the first semiconductor layer 21 relatively distant to the second gate electrode 62 are not easily discharged to the second electrode 52 via the path described above. According to the embodiment, the seventh semiconductor layer 27 is provided as a low injection region of holes such as that described above at a position more distant to the second gate electrode 62 in the second direction X than the first part 24A (the channel part). As a result, the injection amount of holes into the regions of the first semiconductor layer 21 distant to the second gate electrode 62 can be reduced, and the effect of reducing the turn-off switching loss of the semiconductor device 1 due to the turn-on of the second gate electrode 62 can be improved.

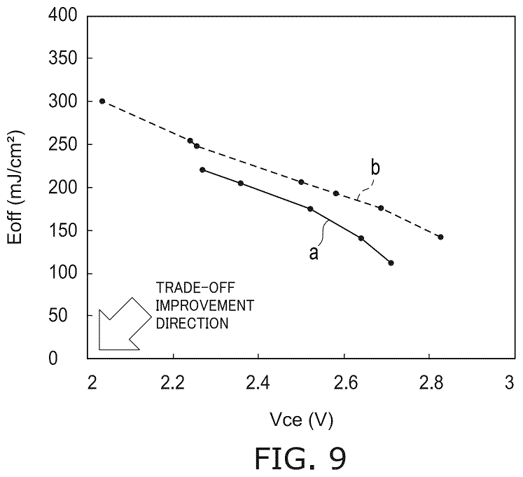

FIG. 9 shows results of a simulation of the relationship between a turn-off switching loss Eoff and an on-voltage Vce (a collector-emitter voltage). Results of a model a that models the semiconductor device 1 of the first embodiment and results of a comparative example b are shown. The comparative example b differs from the model a of the embodiment in that the seventh semiconductor layer 27 is not included.

In an IGBT, there is a trade-off relationship between reducing the turn-off switching loss Eoff and reducing the on-voltage Vce. Based on the simulation results of FIG. 9, according to the embodiment, the trade-off between Eoff and Vce can be better than that of the comparative example by improving the effect of reducing the turn-off switching loss Eoff.

There is a limit to how much the p-type impurity concentration of the fourth semiconductor layer 24 can be reduced to suppress the operation of a parasitic element (an n-p-n transistor) including the eighth semiconductor layer 28 (or the first semiconductor layer 21), the fourth semiconductor layer 24, and the sixth semiconductor layer 26. According to the first embodiment, the design freedom can be increased because the seventh semiconductor layer 27, which has a lower p-type impurity concentration than the fourth semiconductor layer 24, is provided separately from the fourth semiconductor layer 24 as a low injection region of holes.

As shown in FIGS. 3 to 5, multiple seventh semiconductor layers 27 may be arranged in the third direction Y between the second gate electrodes 62 that are adjacent to each other in the second direction X. The sixth semiconductor layer 26 is positioned between the seventh semiconductor layers 27 that are adjacent to each other in the third direction Y.

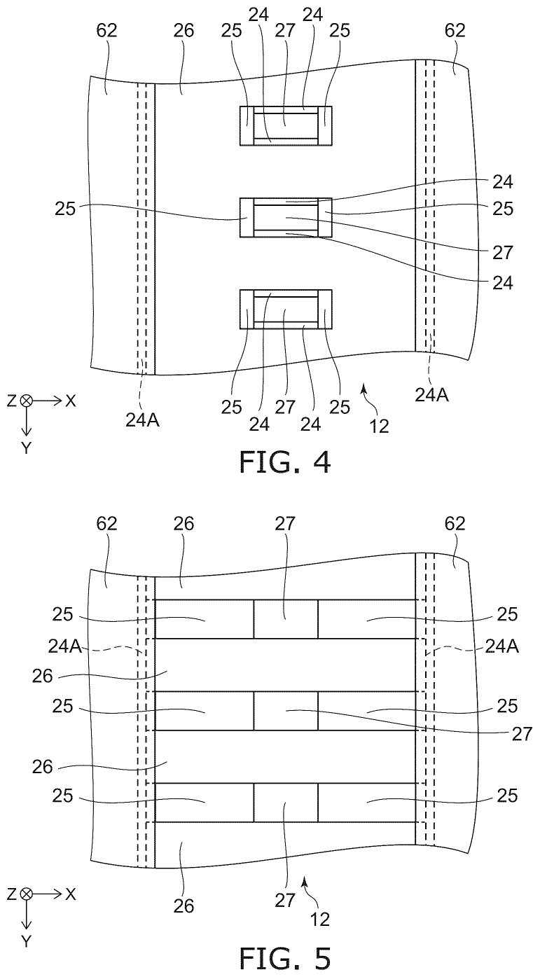

In the example shown in FIGS. 3 and 4, the sixth semiconductor layer 26 is positioned between the seventh semiconductor layer 27 and the first part 24A (the channel part) of the fourth semiconductor layer 24 in the second direction X. The fifth semiconductor layer 25 is positioned between the sixth semiconductor layer 26 and the seventh semiconductor layer 27 in the second direction X. In the example shown in FIG. 4, the fourth semiconductor layer 24 is positioned between the sixth semiconductor layer 26 and the seventh semiconductor layer 27 that are adjacent to each other in the third direction Y.

In the example shown in FIG. 5, the fifth semiconductor layer 25 is positioned between the seventh semiconductor layer 27 and the first part 24A (the channel part) of the fourth semiconductor layer 24 in the second direction X. The sixth semiconductor layer 26 is adjacent to the fifth and seventh semiconductor layers 25 and 27 in the third direction Y. The sixth semiconductor layer 26 is positioned between the first parts 24A (the channel parts) in the second direction X.

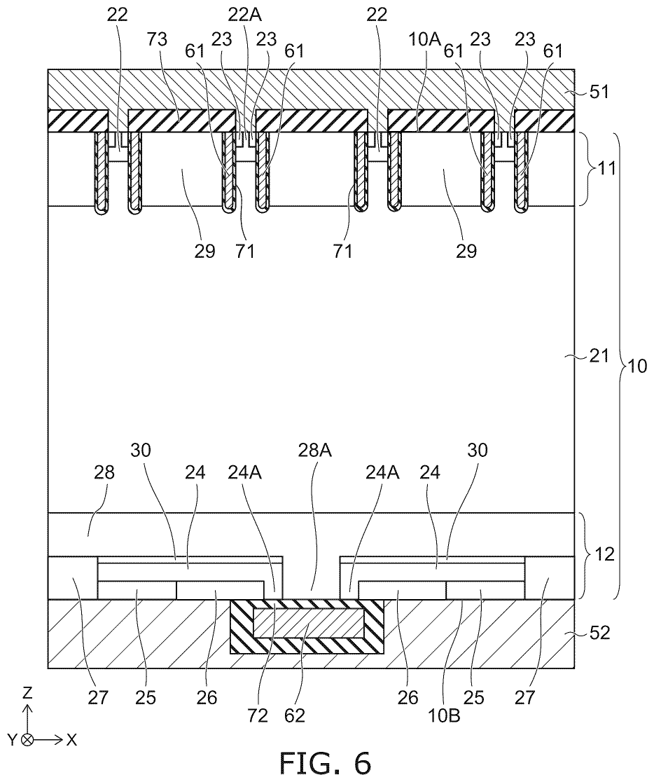

As a modification of the semiconductor device of the first embodiment as shown in FIG. 6, a p-type tenth semiconductor layer 30 may be located between the fourth semiconductor layer 24 and the eighth semiconductor layer 28. The p-type impurity concentration of the tenth semiconductor layer 30 is greater than the p-type impurity concentration of the fourth semiconductor layer 24 and less than the p-type impurity concentration of the fifth semiconductor layer 25.

### Second Embodiment

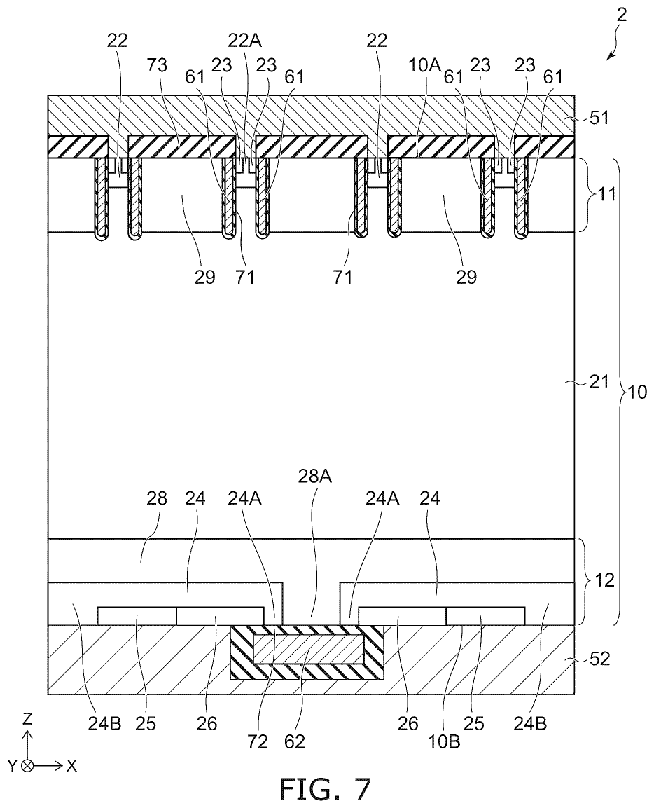

FIG. 7 is a schematic cross-sectional view of a semiconductor device 2 of a second embodiment. The configuration of the semiconductor device 2 of the second embodiment that is different from that of the semiconductor device 1 of the first embodiment will be mainly described.

In the semiconductor device 2 of the second embodiment, the fourth semiconductor layer 24 includes the first part (the channel part) 24A that faces the second gate electrode 62 via the second insulating film 72 in the first direction Z, and a second part 24B that is positioned between the multiple second gate electrodes 62 in the second direction X and contacts the second electrode 52. The second part 24B is positioned between the second electrode 52 and the eighth semiconductor layer 28 in the first direction Z.

The p-type impurity concentration of the second part 24B is less than the p-type impurity concentration of the fifth semiconductor layer 25. The second part 24B functions as a low injection region that injects fewer holes than the fifth semiconductor layer 25. Accordingly, the injection amount of the holes into regions of the first semiconductor layer 21 distant to the second gate electrode 62 can be reduced, and the effect of reducing the turn-off switching loss of the semiconductor device 2 due to the turn-on of the second gate electrode 62 can be improved.

The layout of the second gate electrodes 62 and the layers of the second surface-side region 12 of the semiconductor device 2 of the second embodiment can be the layouts of FIGS. 2 to 5 in which the seventh semiconductor layer 27 is replaced with the second part 24B.

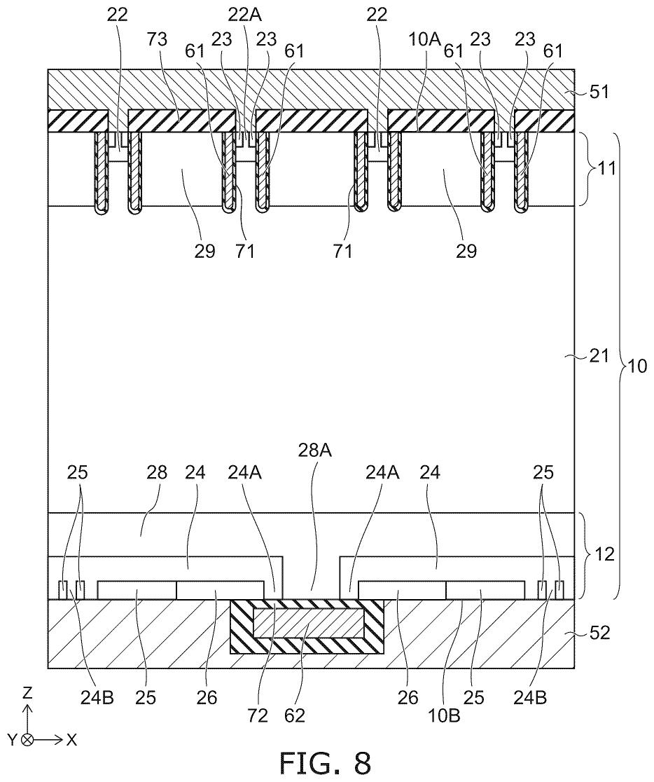

As a modification of the semiconductor device of the second embodiment as shown in FIG. 8, the fifth semiconductor layer 25 may be provided in parts of the second part 24B.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a second electrode;
a semiconductor part positioned between the first electrode and the second electrode in a first direction, the semiconductor part including
a first semiconductor layer of a first conductivity type,
a first surface-side region positioned between the first electrode and the first semiconductor layer in the first direction, and
a second surface-side region positioned between the second electrode and the first semiconductor layer in the first direction;
a plurality of first gate electrodes facing the first surface-side region;
a plurality of first insulating films located between the first surface-side region and the plurality of first gate electrodes;
a plurality of second gate electrodes facing the second surface-side region in the first direction; and
a plurality of second insulating films located between the second surface-side region and the plurality of second gate electrodes,
the first surface-side region including
a second semiconductor layer facing at least one of the plurality of first gate electrodes via the first insulating film, the second semiconductor layer being of a second conductivity type, and
a third semiconductor layer contacting the first electrode, the third semiconductor layer being of the first conductivity type and having a higher first-conductivity-type impurity concentration than the first semiconductor layer,
the second surface-side region including
a fourth semiconductor layer facing at least one of the plurality of second gate electrodes via the second insulating film, the fourth semiconductor layer being of the second conductivity type,
a fifth semiconductor layer contacting the second electrode, the fifth semiconductor layer being of the second conductivity type and having a higher second-conductivity-type impurity concentration than the second and fourth semiconductor layers,
a sixth semiconductor layer contacting the second electrode, the sixth semiconductor layer being of the first conductivity type and having a higher first-conductivity-type impurity concentration than the first semiconductor layer, and
a seventh semiconductor layer contacting the second electrode, the seventh semiconductor layer being of the second conductivity type and having a lower second-conductivity-type impurity concentration than the fourth and fifth semiconductor layers,
the seventh semiconductor layer being positioned between the plurality of second gate electrodes in a second direction orthogonal to the first direction.

2. The device according to claim 1, wherein
the second surface-side region further includes an eighth semiconductor layer positioned between the first semiconductor layer and the fourth semiconductor layer, the eighth semiconductor layer being of the first conductivity type and having a higher first-conductivity-type impurity concentration than the first semiconductor layer.

3. The device according to claim 1, wherein
the fifth semiconductor layer is positioned between the sixth semiconductor layer and the seventh semiconductor layer in the second direction.

4. The device according to claim 1, wherein
the plurality of first gate electrodes is located in trenches with the plurality of first insulating films interposed, the trenches being formed in the first surface-side region, and
the plurality of first gate electrodes faces the second semiconductor layer via the plurality of first insulating films in the second direction.

5. The device according to claim 1, wherein
the first surface-side region further includes a ninth semiconductor layer positioned between first gate electrodes among the plurality of first gate electrodes adjacent to each other in the second direction, the ninth semiconductor layer being of the second conductivity type, the ninth semiconductor layer being deeper than the second semiconductor layer.

6. A semiconductor device, comprising:
a first electrode;
a second electrode;
a semiconductor part positioned between the first electrode and the second electrode in a first direction, the semiconductor part including
a first semiconductor layer of a first conductivity type,
a first surface-side region positioned between the first electrode and the first semiconductor layer in the first direction, and
a second surface-side region positioned between the second electrode and the first semiconductor layer in the first direction;
a plurality of first gate electrodes facing the first surface-side region;
a plurality of first insulating films located between the first surface-side region and the plurality of first gate electrodes;
a plurality of second gate electrodes facing the second surface-side region in the first direction; and
a plurality of second insulating films located between the second surface-side region and the plurality of second gate electrodes,
the first surface-side region including
a second semiconductor layer facing at least one of the plurality of first gate electrodes via the first insulating film, the second semiconductor layer being of a second conductivity type, and
a third semiconductor layer contacting the first electrode, the third semiconductor layer being of the first conductivity type and having a higher first-conductivity-type impurity concentration than the first semiconductor layer,
the second surface-side region including
a fourth semiconductor layer of the second conductivity type,
a fifth semiconductor layer contacting the second electrode, the fifth semiconductor layer being of the second conductivity type and having a higher second-conductivity-type impurity concentration than the second and fourth semiconductor layers, and
a sixth semiconductor layer contacting the second electrode, the sixth semiconductor layer being of the first conductivity type and having a higher first-conductivity-type impurity concentration than the first semiconductor layer,
the fourth semiconductor layer including
a first part facing at least one of the plurality of second gate electrodes via the second insulating film, and
a second part positioned between the plurality of second gate electrodes in a second direction orthogonal to the first direction, the second part contacting the second electrode.

7. The device according to claim 6, wherein
the second surface-side region further includes an eighth semiconductor layer positioned between the first semiconductor layer and the fourth semiconductor layer, the eighth semiconductor layer being of the first conductivity type and having a higher first-conductivity-type impurity concentration than the first semiconductor layer.

8. The device according to claim 6, wherein
the fifth semiconductor layer is positioned between the sixth semiconductor layer and the second part of the fourth semiconductor layer in the second direction.

9. The device according to claim 6, wherein
the plurality of first gate electrodes is located in trenches with the plurality of first insulating films interposed, the trenches being formed in the first surface-side region, and
the plurality of first gate electrodes faces the second semiconductor layer via the plurality of first insulating films in the second direction.

10. The device according to claim 6, wherein
the first surface-side region further includes a ninth semiconductor layer positioned between first gate electrodes among the plurality of first gate electrodes adjacent to each other in the second direction, the ninth semiconductor layer being of the second conductivity type, the ninth semiconductor layer being deeper than the second semiconductor layer.
